(19) United States
(12) Patent Application Publication
(10) Pub. No.: US 2026/0068291 A1
(43) Pub. Date: Mar. 5, 2026

(54) SEMICONDUCTOR DEVICE AND METHOD OF FABRICATING THE SAME

(71) Applicant: LX Semicon Co.,Ltd., Daejeon (KR)

(72) Inventor: Kee Joon CHOI, Daejeon (KR)

(73) Assignee: LX Semicon Co.,Ltd., Daejeon (KR)

(21) Appl. No.: 19/310,095

(22) Filed: Aug. 26, 2025

(30) Foreign Application Priority Data
Aug. 27, 2024 (KR) 10-2024-0115352
May 28, 2025 (KR) 10-2025-0069545

(51) Int. Cl. H10D 84/00; H10D 84/01

(52) U.S. Cl. CPC H10D 84/221; H10D 84/0112

(57) ABSTRACT

The present specification discloses a semiconductor device including dual trenches and a method of fabricating the same. The semiconductor device includes a first region where a plurality of first semiconductor elements are provided on a substrate, a second region where a plurality of second semiconductor elements are provided on the substrate, an isolation region provided in the substrate between the first region and the second region, shallow trenches formed in the substrate of the first region and the second region, a shallow trench insulating film formed inside each of the shallow trenches, a deep trench formed in the substrate of the isolation region, and a deep trench insulating film formed inside the deep trench, in which a well tap structure is not provided in the substrate between the first region and the second region.

### CROSS-REFERENCE TO RELATED APPLICATION

This application claims priority to and the benefit of Korean Patent Application Nos. 10-2024-0115352 and 10-2025-0069545, respectively filed Aug. 27, 2024 and May 28, 2025, the entire disclosures of all these applications being incorporated by reference into the present application.

### BACKGROUND

### Field

The present specification relates to a semiconductor device and a method of fabricating the same.

### Discussion of Related Art

For electrical separation of a plurality of semiconductor elements in one chip, a shallow trench, a deep trench, and a junction isolation structure are applied.

And, when a deep trench structure is used, a complicated step for filling the trench structure is required, causing an increase in the number of fabricating steps.

### SUMMARY

An embodiment of the present specification is directed to a semiconductor device and a method of fabricating the same capable of reducing a fabrication cost and improving FAB compatibility through dual trench.

An embodiment of the present specification is directed to a semiconductor device and a method of fabricating the same capable of increasing the integration of semiconductor element chips by omitting a structure of a well tap in an isolation region and further securing an effective area where semiconductor element chips can be formed.

The problems addressed by the present disclosure are not limited to those described above, and other problems not described will be clearly understood by those skilled in the art from the following description.

A semiconductor device according to an embodiment of the present specification includes: a first region where a plurality of first semiconductor elements are provided on a substrate; a second region where a plurality of second semiconductor elements are provided on the substrate; an isolation region provided in the substrate between the first region and the second region; shallow trenches formed in the substrate of the first region and the second region; shallow trench insulating films formed inside the shallow trenches; a deep trench formed in the substrate in the isolation region; and a deep trench insulating film formed inside the deep trench, in which a structure of a well tap is not provided in the substrate between the first region and the second region.

The semiconductor device according to the embodiment of the present specification may further include: a first conduction type high-concentration first well region formed in the substrate; and a second conduction type high-concentration well region and a first conduction type high-concentration second well region formed on the The deep trench may be formed across the second conduction type high-concentration well region, the first conduction type high-concentration second well region, and the first conduction type high-concentration first well region.

The semiconductor device according to the embodiment of the present specification may further include: a first conduction type high-concentration first well region formed in the substrate; a second conduction type doped well region formed on the first conduction type high-concentration first well region; a first conduction type high-concentration second well region formed on an upper portion of the first conduction type high-concentration first well region and in the second conduction type doped well region; and a second conduction type high-concentration well region formed on an upper portion of the first conduction type high-concentration first well region.

The deep trench may be formed across the second conduction type high-concentration well region, the first conduction type high-concentration second well region, the second conduction type doped well region, and the first conduction type high-concentration first well region.

The shallow trench may be formed in the first conduction type high-concentration second well region and the second conduction type high-concentration well region.

A well tap structure may be formed in the substrate on one side of the first region and the second region, and a well tap structure may not be formed in the substrate where the first region and the second region face each other.

The well tap structure may be formed in the substrate between the shallow trenches on one side of the first region and the second region, and may not be formed in the substrate that abuts to the deep trench.

Each of the first semiconductor elements may include a first gate formed on the substrate of the first region and first conduction type high-concentration doped regions formed in the substrate below both sides of the first gate, and each of the second semiconductor elements may include a second gate formed on the substrate of the second region and second conduction type high-concentration doped regions formed in the substrate below both sides of the second gate.

Each of the first semiconductor elements may include a second conduction type diode formed in the substrate of the first region, and each of the second semiconductor elements may include a first conduction type diode formed in the substrate of the second region.

A method of fabricating a semiconductor device according to an embodiment of the present specification includes: preparing a first region having a plurality of first semiconductor elements on a substrate and a second region having a plurality of second semiconductor elements on the substrate; preparing an isolation region in the substrate between the first region and the second region; forming shallow trenches in the substrate of the first region and the second region; forming a deep trench in the substrate in the isolation region; and forming a shallow trench insulating film inside each of the shallow trench and forming a deep trench insulating film inside the deep trench.

The method of fabricating a semiconductor device according to the embodiment of the present specification may further include: forming a first conduction type high-concentration first well region in the substrate; and forming a second conduction type high-concentration well region and a first conduction type high-concentration second well region on the first conduction type high-concentration first well region.

The forming of the deep trench may include forming the deep trench across the second conduction type high-concentration well region, the first conduction type high-concentration second well region, and the first conduction type high-concentration first well region.

The method of fabricating a semiconductor device according to the embodiment of the present specification may further include: forming a first conduction type high-concentration first well region in the substrate; forming a second conduction type doped well region on the first conduction type high-concentration first well region; forming a first conduction type high-concentration second well region on an upper portion of the first conduction type high-concentration first well region and in the second conduction type doped well region; and forming a second conduction type high-concentration well region on an upper portion of the first conduction type high-concentration first well region.

The forming of the deep trench may include forming the deep trench across the second conduction type high-concentration well region, the first conduction type high-concentration second well region, the second conduction type doped well region, and the first conduction type high-concentration first well region.

The forming of the shallow trenches may include forming the shallow trenches in the first conduction type high-concentration second well region and the second conduction type high-concentration well region.

The method of fabricating a semiconductor device according to the embodiment of the present specification may further include forming a well tap structure in the substrate on one side of the first region and the second region and not forming a well tap structure in the substrate where the first region and the second region face each other.

The forming of the well tap structure may include forming the well tap structure in the substrate between the shallow trenches on one side of the first region and the second region and not forming a well tap structure in the substrate that abuts to the deep trench.

The preparing of the first region having the first semiconductor elements may include forming a first gate on the substrate of the first region, and forming first conduction type high-concentration doped regions in a second conduction type high-concentration well region in the substrate below both sides of the first gate, and the preparing of the second region having the second semiconductor elements may include forming a second gate on the substrate of the second region, and forming second conduction type high-concentration doped regions in the first conduction type high-concentration second well region in the substrate below both sides of the second gate.

The preparing of the first region having the first semiconductor elements may include forming a second conduction type diode in a first conduction type high-concentration second well region in the substrate of the first region, and the preparing of the second region having the second semiconductor elements may include forming a first conduction type diode in a second conduction type high-concentration well region in the substrate of the second region.

Details according to various embodiments of the present specification in addition to the solutions of the above problems are included in the following description and the drawings.

According to the embodiments of the present specification, a well tap structure is omitted in the isolation region between the first region and the second region, and the deep trench having a small width compared to the existing structure is provided, thereby reducing a chip size. As a result, it is possible to increase the number of chips to be formed on an entire wafer.

The effects of the present specification are not limited to the effects described above, and other effects not described will be understood by those skilled in the art to which the technical idea of the present specification belongs, from the following description.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a plan view of a semiconductor device according to an embodiment of the present specification;

FIG. 2 is a cross-sectional view taken along line I-I′ in FIG. 1;

FIG. 3 is a cross-sectional view taken along line II-II′ in FIG. 1;

FIGS. 4A to 4G are cross-sectional views of a fabricating process of the semiconductor device according to the embodiment of the present specification;

FIG. 5 is a plan view of a semiconductor device according to another embodiment of the present specification;

FIG. 6 is a cross-sectional view taken along line III-III′ in FIG. 5;

FIG. 7 is a cross-sectional view taken along line IV-IV′ in FIG. 5;

FIGS. 8A to 8H are cross-sectional views of a fabricating process of the semiconductor device according to another embodiment of the present specification;

FIG. 9 is a plan view of a semiconductor device according to still another embodiment of the present specification;

FIG. 10 is a cross-sectional view taken along line V-V′ in FIG. 9;

FIG. 11 is a cross-sectional view taken along line VI-VI′ in FIG. 9; and

FIGS. 12A to 12G are cross-sectional views of a fabricating process of the semiconductor device according to still another embodiment of the present specification.

### DETAILED DESCRIPTION OF EXEMPLARY EMBODIMENTS

The advantages and features of the present specification, and methods of achieving them will be apparent from the embodiments described in detail below in conjunction with the accompanying drawings. However, the present specification is not limited to the following embodiments disclosed herein, but may be implemented in various different forms; rather, the present embodiments are provided to make the disclosure of the present specification complete and to enable those skilled in the art to fully comprehend the scope of the present specification.

The shapes, sizes, proportions, angles, numbers, and the like of elements shown in the drawings to illustrate embodiments of the present specification are merely illustrative and are not intended to be limiting. Identical reference numerals may designate identical components throughout the description. Further, in describing the present specification, detailed descriptions of related known technologies may be omitted so as not to obscure the essence of the present specification. The terms such as “including,” “having,” and “consisting of” as used herein are generally intended to allow other components to be added unless the terms are used with the term “only.” References to components of a singular noun include the plural of that noun, unless specifically stated otherwise.

In the interpretation of components, they are construed to include margins of error, even if not explicitly stated.

When describing a positional relationship, for example, “on top of,” “above,” “below,” “next to,” or “adjacent to” describes the positional relationship of two parts, one or more other parts may be located between the two parts, unless “immediately,” “directly,” or “near to” is used.

When describing a temporal relationship, “after,” “subsequently to,” “following,” or, “before” describes a temporal antecedent or consequent relationship, which may not be continuous unless “immediately,” or “directly” is used.

The first, the second, and so on are used to describe various components, but these components are not limited by these terms. These terms are used only to distinguish one component from another. Therefore, a first component referred to below may be a second component within the technical spirit of the present disclosure.

Terms such as first, second, A, B, (a), or (b) may be used to describe elements of the embodiments of the present specification. Such terms are intended only to distinguish one component from another and are not intended to define the nature, sequence, order, or number of such components.

When a component is described as being “connected,” “coupled”, “accessed,” or “attached” to another component, it is to be understood that the component may be directly connected, coupled, accessed, or attached to the other component, but that there may also be other components interposed between the respective components which may be indirectly connected, coupled, accessed, or attached, unless specifically stated otherwise.

When a component is described as being “in contact” or “overlapping” with another component, it is to be understood that the component may be in direct contact or overlap with the other component, but other components may also be “interposed” between these components, resulting in indirect contact or overlap, unless specifically stated otherwise.

It should be understood that the term “at least one” includes all possible combinations of one or more related components. For example, the meaning of “at least one of the first, second, and third components” may be understood to include not only the first, second, or third component, but also any combination of two or more of the first, second, and third components.

The terms “the first direction,” “the second direction,” “the third direction,” “the X-axis direction,” “the Y-axis direction,” and “the Z-axis direction” are not to be interpreted solely as a geometric relationship in which the relationship to one another is perpendicular, but may refer to a broader range of orientations in which the configurations of the present specification may function.

Each of the features of various embodiments of the present specification may be coupled or combined with one another in whole or in part, and may be technologically interlocked and operated in various ways, and each of the embodiments may be carried out independently or in conjunction with one another.

Hereinafter, various embodiments of the present specification will be described in detail with reference to the accompanying drawings.

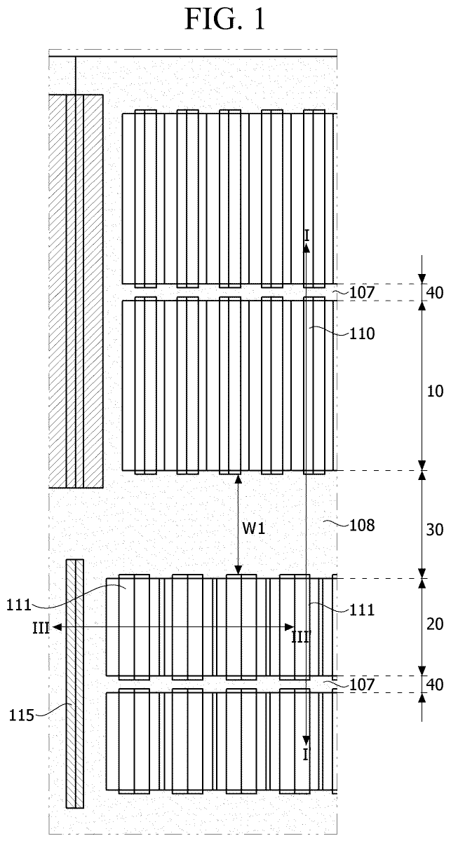

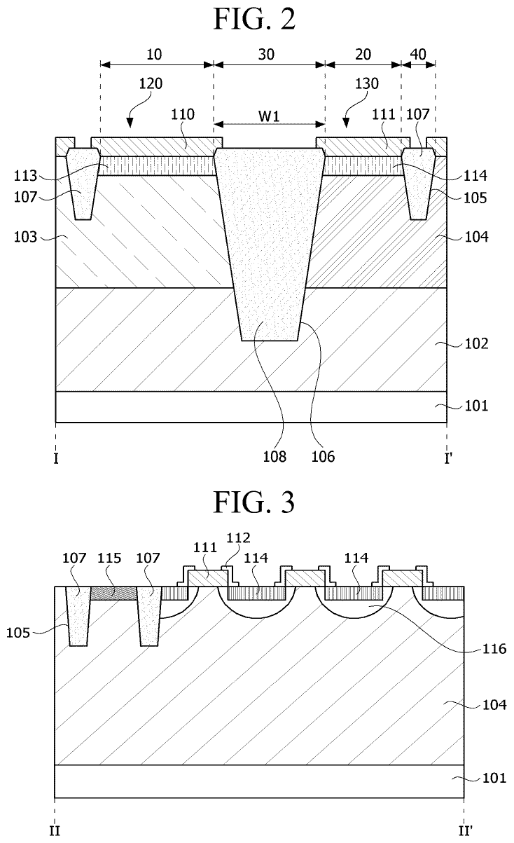

FIG. 1 is a plan view of a semiconductor device according to an embodiment of the present specification. FIG. 2 is a cross-sectional view taken along line I-I′ in FIG. 1. FIG. 3 is a cross-sectional view taken along line II-II′ in FIG. 1.

Referring to FIGS. 1 to 3, the semiconductor device according to the embodiment of the present specification may include a first region 10 having a plurality of first semiconductor elements 120 on a first conduction type substrate 101, a second region 20 having a plurality of second semiconductor elements 130 on the first conduction type substrate 101, a first isolation region 30 positioned between the first region 10 and the second region 20 to separate the first region 10 and the second region 20 from each other, and second isolation regions 40 positioned in the first region 10 and the second region 20, respectively, to divide the plurality of first and second semiconductor elements 120 and 130.

Here, a first conduction type high-concentration first well region 102 may be formed in the first conduction type substrate 101. A second conduction type high-concentration well region 103 and a first conduction type high-concentration second well region 104 may be formed in the first conduction type high-concentration first well region 102 in the first conduction type substrate 101.

The first semiconductor element 120 may include a first gate 110 made of polysilicon. The second semiconductor element 130 may include a second gate 111.

The first and second gates 110 and 111 are formed of a conductive material, for example, a polysilicon material. However, embodiments of the present specification are not limited thereto.

A sidewall insulating film 112 may be formed on side surfaces of the first and second gates 110 and 111.

Referring to FIGS. 2 and 3, the first region 10 and the second region 20 may include the first and second gates 110 and 111 provided on an upper portion of the first conduction type substrate 101, and first conduction type high-concentration doped regions 113 and second conduction type high-concentration doped regions 114 provided below the first and second gates 110 and 111.

A well tap 115 may be formed in the first conduction type substrate 101 between shallow trenches 105 positioned on one side of the first region 10 and the second region 20. In this case, the well tap 115 may serve to apply a voltage to a well region. Specifically, the well tap 115 may be formed in the first conduction type high-concentration second well region 104 in the first conduction type substrate 101. Meanwhile, the well tap 115 may not be provided in the first conduction type substrate 101 positioned between the first region 10 and the second region 20.

In an existing structure, the structure of the well tap 115 for applying a voltage to the well region is formed on one side of the first region 10 and the second region 20 and between these regions; however, in the present specification, since the structure of the well tap 115 is formed on one side of the first region 10 and the second region 20, the structure of the well tap 115 does not need to be formed between the first region 10 and the second region 20. The reason is that the structure of the well tap 115 is omitted between the first region 10 and the second region 20, thereby further securing a space where semiconductor element chips can be formed, by an area of the well tap structure that is omitted in the first conduction type substrate 101.

Accordingly, in the present specification, since the well tap structure does not need to be formed between the first region 10 and the second region 20, the number of semiconductor element chips that will be formed on the first conduction type substrate 101 can be increased as much, and as a result, the integration of the semiconductor element chips can be increased.

The first conduction type high-concentration doped regions 113 may be formed in the second conduction type high-concentration well region 103 below both sides of the first gate 110. The second conduction type high-concentration doped regions 114 may be formed in the first conduction type high-concentration second well region 104 below both sides of the second gate 111.

Referring to FIG. 3, the second conduction type high-concentration doped regions 114 may be formed in second conduction type low-concentration doped regions 116 formed in the first conduction type high-concentration second well region 104.

The first isolation region 30 may include a deep trench 106. The deep trench 106 may be formed within a boundary region between the second conduction type high-concentration well region 103 and the first conduction type high-concentration second well region 104. Specifically, the deep trench 106 may be formed within the second conduction type high-concentration well region 103 and the first conduction type high-concentration second well region 104 that abut to each other. Here, the deep trench 106 has a first width W1 and has a first depth d1. In this case, the first width first width W1 may have a small width compared to the existing structure. The first conduction type may be P type, and the second conduction type may be N type.

The deep trench 106 may be formed to the first conduction type high-concentration first well region 102 in the first conduction type substrate 101. According to the present embodiment, the deep trench 106 may be formed by a two-step etching process. However, embodiments of the present specification are not limited thereto.

The deep trench 106 may be formed by etching from an upper surface of the first conduction type substrate 101 at a predetermined depth and may be formed to be narrowed and inclined downward. This is because the deeper an etching depth becomes, the lower the concentration of an etching gas material becomes. The depth of the deep trench 106 may extend to a lower portion of the first conduction type substrate 101 and may be deeper than the second conduction type high-concentration well region 103 and the first conduction type high-concentration second well region 104. The deep trench 106 may be a region that is applied to insulate the first region 10 and the second region 20 from each other.

Accordingly, in the present invention, a well tap structure that is formed to apply a voltage to a well region in the existing structure is omitted in the first conduction type substrate 101 between the first region 10 and the second region 20, and the shallow trenches 105 on both sides of the well tap structure are replaceable with one deep trench 106. As a result, the width of the deep trench 106 that is formed to insulate the first region 10 and the second region 20 from each other can be reduced as much.

Accordingly, in the present specification, a well tap structure is omitted in the first conduction type substrate 101 between the first region 10 and the second region 20, thereby increasing an area for forming semiconductor element chips provided on the first conduction type substrate 101. In this way, since the number of semiconductor element chips to be formed on the first conduction type substrate 101 can be increased, the integration of the semiconductor element chips can be increased.

The second isolation regions 40 may include one or more shallow trenches 105 provided to insulate multiple semiconductor element structures from each other. The shallow trenches 105 may be provided to be separated from the semiconductor elements 110 and 111 in the first region 10 and the second region 20 on right and left sides. Specifically, the shallow trenches 105 in the first region 10 may be provided to be separated from the first semiconductor elements 110 in the first region 10.

The shallow trenches 105 in the second region 20 may be provided to be separated from the second semiconductor elements 111 in the second region 20. Here, the shallow trenches 105 may have a width smaller than the first width W1 of the deep trench 106. The shallow trenches 105 may have a depth smaller than the first depth d1 of the deep trench 106.

The shallow trenches 105 may be filled with a shallow trench insulating film 107. The deep trench 106 may be filled with a deep trench insulating film 108.

In this way, in the present specification, a well tap structure is omitted in the first isolation region 30 between the first region 10 and the second region 20, and the deep trench 106 having the small first width W1 compared to the existing structure is provided, thereby further securing an area for semiconductor element chips while achieving high-voltage endurance. As a result, the integration of the semiconductor element chips to be formed on the first conduction type substrate 101 can be increased as much.

Hereinafter, a method of fabricating a semiconductor device according to the embodiment of the present specification will be described with reference to the accompanying drawings.

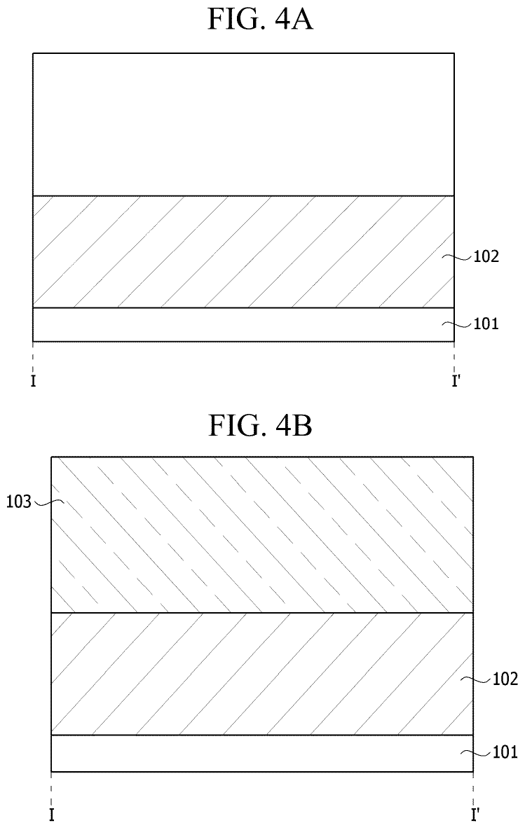

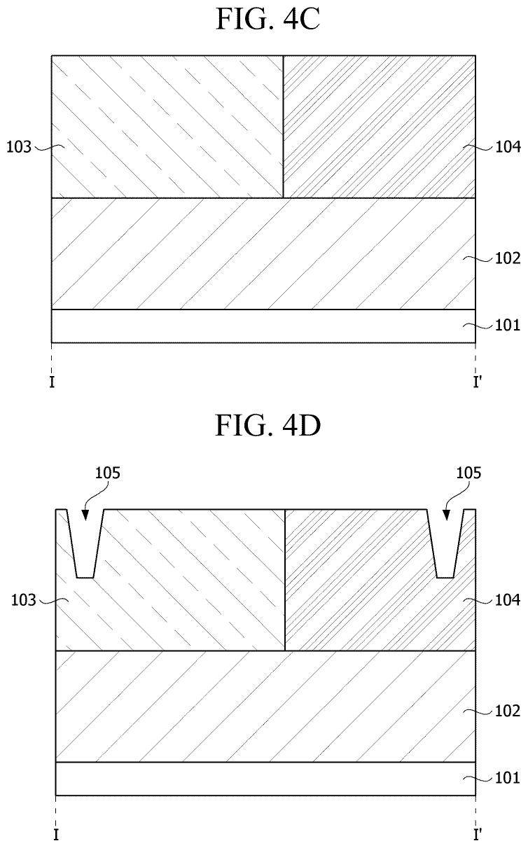

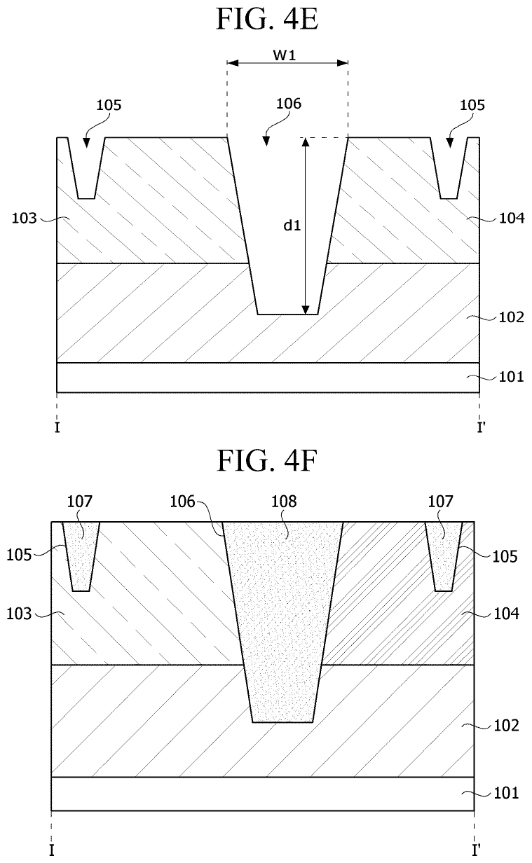

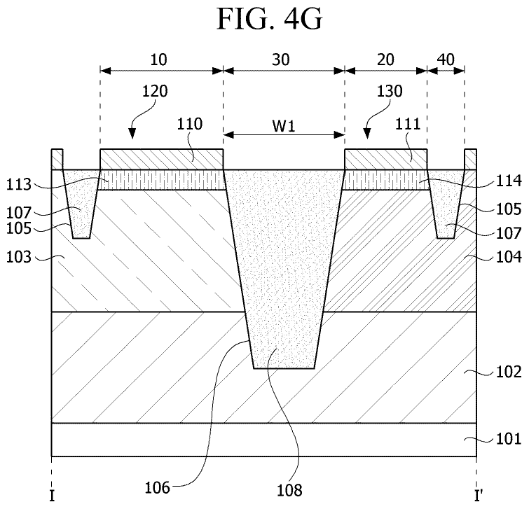

FIGS. 4A to 4G are cross-sectional views of a fabricating process of the semiconductor device according to the embodiment of the present specification.

Referring to FIG. 4A, boron of the first conduction type may be implanted in the first conduction type substrate 101 by blank implantation to form the first conduction type high-concentration first well region 102 in the first conduction type substrate 101. The first conduction type may be p type.

Next, referring to FIG. 4B, phosphorus of the second conduction type may be implanted in the first conduction type substrate 101 by blank implantation to form the second conduction type high-concentration well region 103 on the first conduction type high-concentration first well region 102 in the first conduction type substrate 101. In this case, the second conduction type may be n type.

Next, referring to FIG. 4C, boron of the first conduction type may be ion-implanted into the first conduction type substrate 101 using a mask (not illustrated) to form the first conduction type high-concentration second well region 104 on the first conduction type high-concentration first well region 102. In this case, the second conduction type high-concentration well region 103 and the first conduction type high-concentration second well region 104 are in contact with each other.

Next, referring to FIG. 4D, the second conduction type high-concentration well region 103 and the first conduction type high-concentration second well region 104 in the first conduction type substrate 101 may be etched using a shallow trench forming mask (not illustrated) to form the shallow trenches 105 in the second conduction type high-concentration well region 103 and the first conduction type high-concentration second well region 104.

Next, referring to FIG. 4E, a contact portion of the second conduction type high-concentration well region 103 and the first conduction type high-concentration second well region 104 in the first conduction type substrate 101 may be etched using a deep trench forming mask (not illustrated) to form the deep trench 106. In this case, the deep trench 106 may be formed in the second conduction type high-concentration well region 103 and the first conduction type high-concentration second well region 104. Here, the deep trench 106 has the first width W1 and has the first depth d1. In this case, the first width W1 may be a small (shrink) width compared to the existing structure. While details will be described below, the reason is that a well tap structure that is formed in the existing structure can be omitted, thereby securing a marginal area where semiconductor element chips can be formed, on the first conduction type substrate 101 as much. As a result, even when the first width W1 of the deep trench 106 is small (shrink), an area capable of insulating the first region 10 and the second region 20 can be secured.

The deep trench 106 may be formed to the first conduction type high-concentration first well region 102 in the first conduction type substrate 101. The deep trench 106 may be formed in the second conduction type high-concentration well region 103 and the first conduction type high-concentration second well region 104 that are in contact with each other. In the present embodiment, the deep trench 106 may be formed by a two-step etching process. However, embodiments of the present specification are not limited thereto.

In this case, the deep trench 106 may be formed by etching from an upper surface of the first conduction type substrate 101 at a predetermined depth and may be formed to be narrowed and inclined downward. This is because the deeper an etching depth becomes, the lower the concentration of an etching gas material becomes. The depth of the deep trench 106 may extend to the lower portion of the first conduction type substrate 101 and may be deeper than the second conduction type high-concentration well region 103 and the first conduction type high-concentration second well region 104.

Next, referring to FIG. 4F, the shallow trenches 105 and the deep trench 106 are filled with an insulating material, and the shallow trench insulating film 107 and the deep trench insulating film 108 may be formed inside the shallow trenches 105 and the deep trench 106, respectively. In this case, the shallow trench insulating film 107 and the deep trench insulating film 108 may have the same height as the upper surface of the first conduction type substrate 101 or may protrude from the upper surface. The deep trench insulating film 108 may insulate the first region 10 and the second region 20 from each other.

Next, referring to FIG. 4G, a conductive material may be deposited in the first region 10 and the second region 20, and then, may be selectively etched through a mask process to form the first gates 110 and the second gates 111. In this case, the conductive material may be formed of, for example, a polysilicon material. However, embodiments of the present specification are not limited thereto.

A hard mask insulating film (gate hard mask) (not illustrated) may be formed on upper portions of the first and second gates 110 and 111. The hard mark insulating film (not illustrated) can prevent the upper portions of the first and second gates 110 and 111 from being damaged in the etching process.

The sidewall insulating film (see reference number 112 in FIG. 3) may be formed on the side surfaces of the first and second gates 110 and 111.

Next, referring to FIG. 4G, the first conduction type high-concentration doped regions 113 and the second conduction type high-concentration doped regions 114 may be formed in the first conduction type substrate 101 below side surfaces of the first and second gates 110 and 111 that compose the first and second semiconductor elements 120 and 130 in the first region 10 and the second region 20, respectively. In this case, the first conduction type high-concentration doped regions 113 may be formed in the second conduction type high-concentration well region 103 of the first region 10. The first conduction type high-concentration doped regions 113 may be formed in the second conduction type high-concentration well region 103 below both sides of the first gate 110. The first semiconductor element 120 may include the first gate 110 and the first conduction type high-concentration doped regions 113.

The second conduction type high-concentration doped regions 114 may be formed in the first conduction type high-concentration second well region 104 of the second region 20. In this case, the second conduction type high-concentration doped regions 114 may be formed in the first conduction type high-concentration second well region 104 below both sides of the second gate 111. The second semiconductor element 130 may include the second gate 111 and the second conduction type high-concentration doped regions 114.

Referring to FIG. 3, the well tap 115 may be formed in the first conduction type substrate 101 between the shallow trenches 105 on one side of the second region 20. In this case, the well tap 115 may serve to apply a voltage to a well region.

Specifically, the well tap 115 may be formed in the first conduction type high-concentration second well region 104 in the first conduction type substrate 101. Meanwhile, the well tap well tap 115 may not be provided in the first conduction type substrate 101 between the first region 10 and the second region 20.

In the existing structure, the structure of the well tap 115 for applying a voltage to a well region is formed on one side of the first region 10 and the second region 20 and between these regions; however, in the present specification, since the structure of the well tap 115 is formed on one side of the first region 10 and the second region 20, the structure of the well tap 115 does not need to be formed between the first region 10 and the second region 20. The reason is that the structure of the well tap 115 is omitted between the first region 10 and the second region 20, thereby further securing a space where semiconductor element chips can be formed, by an area of the well tap structure that is omitted in the first conduction type substrate 101.

Accordingly, in the present specification, since a well tap structure does not need to be formed between the first region 10 and the second region 20, the number of semiconductor element chips to be formed on the first conduction type substrate 101 can be increases as much, and as a result, the integration of the semiconductor element chips can be increased.

On the other hand, another embodiment of the present specification will be described in detail with reference to the accompanying drawings described below.

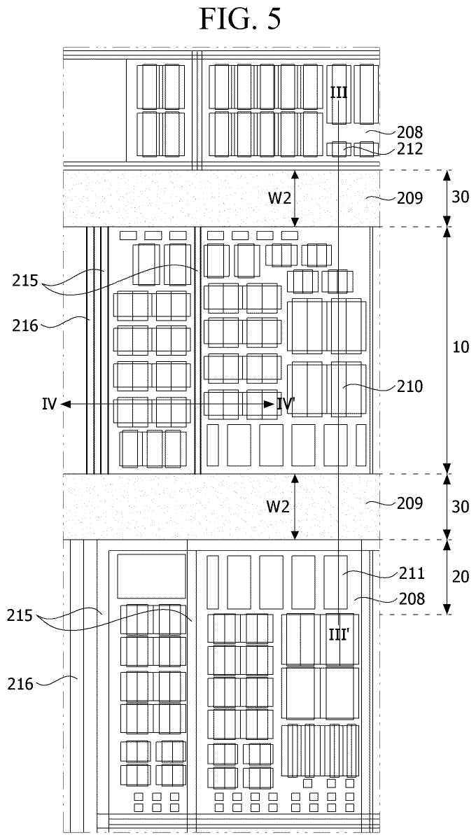

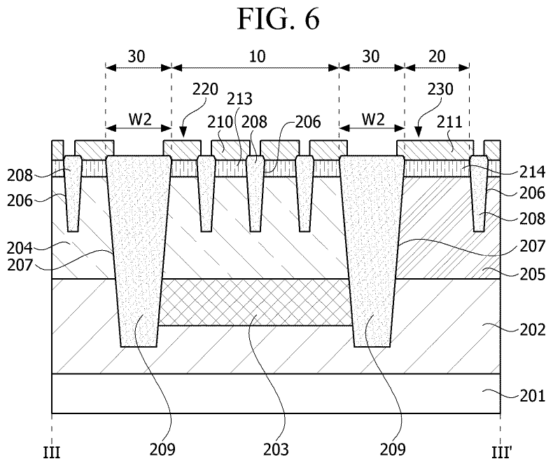

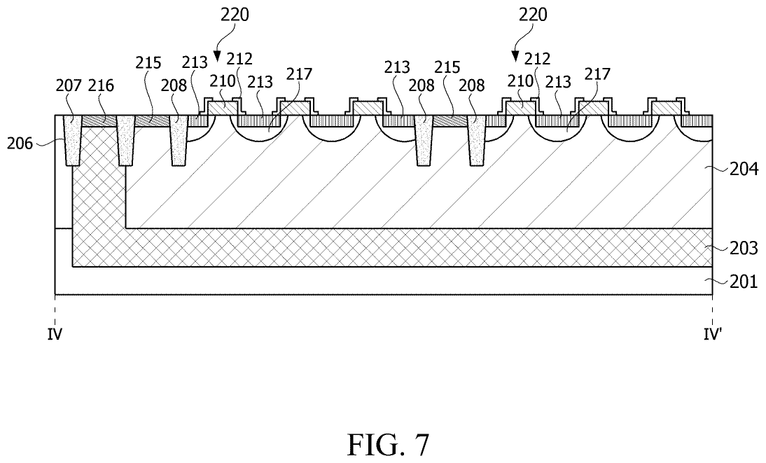

FIG. 5 is a plan view of a semiconductor device according to another embodiment of the present specification. FIG. 6 is a cross-sectional view taken along line III-III′ in FIG. 5. FIG. 7 is a cross-sectional view taken along line IV-IV′ in FIG. 5.

Referring to FIGS. 5 to 7, the semiconductor device according to another embodiment of the present specification may include a first region 10 having a plurality of first semiconductor elements 220 on a first conduction type substrate 201, a second region 20 having a plurality of second semiconductor elements 230 on the first conduction type substrate 201, and an isolation region 30 positioned between the first region 10 and the second region 20 to separate the first region 10 and the second region 20 from each other.

Here, a first conduction type high-concentration first well region 202 may be formed in the first conduction type substrate 201. A second conduction type doped well region 203 may be formed on the first conduction type high-concentration first well region 202 in the first conduction type substrate 201.

A first conduction type high-concentration second well region 204 and a second conduction type high-concentration well region 205 may be formed in the first conduction type high-concentration first well region 202 and the second conduction type doped well region 203 in the first conduction type substrate 201. Specifically, the first conduction type high-concentration second well region 204 may be formed in the first conduction type high-concentration first well region 202 and the second conduction type doped well region 203. The second conduction type high-concentration well region 205 may be formed in the first conduction type high-concentration first well region 202.

The first semiconductor element 220 may include a first gate 210 made of polysilicon. The second semiconductor element 230 may include a second gate 211.

The first and second gates 210 and 211 may be formed of a conductive material, for example, a polysilicon material. However, embodiments of the present specification are not limited thereto.

Referring to FIG. 7, a sidewall insulating film 212 may be formed on side surfaces of the first and second gates 210 and 211.

Referring to FIGS. 6 and 7, the first region 10 and the second region 20 may include the first and second gates 210 and 211 provided on an upper portion of the first conduction type substrate 201, and second conduction type high-concentration doped regions 213 and first conduction type high-concentration doped regions 214 provided below the first and second gates 210 and 211, respectively.

Specifically, the second conduction type high-concentration doped regions 213 may be formed in the first conduction type high-concentration second well region 204 formed in the first conduction type substrate 201 below both sides of the first gate 210 in the first region 10. In this case, referring to FIG. 7, the second conduction type high-concentration doped regions 213 may be formed in second conduction type low-concentration doped regions 217 formed in the first conduction type high-concentration second well region 204.

The first conduction type high-concentration doped regions 214 may be formed in the second conduction type high-concentration well region 205 formed in the first conduction type substrate 201 below both sides of the second gate 211 in the second region 20.

Well taps 215 and 216 may be formed in the first conduction type substrate 201 between shallow trenches 206 on one side of the first region 10. In this case, the well taps 215 and 216 may serve to apply a voltage to a well region. Specifically, the well taps 215 and 216 may be formed in the first conduction type high-concentration second well region 204 and the second conduction type high-concentration well region 205 in the first conduction type substrate 201. Meanwhile, the well taps 215 and 216 may not be provided in the first conduction type substrate 201 between the first region 10 and the second region 20.

Specifically, in the existing structure, the structure of the well taps 215 and 216 for applying a voltage to a well region is formed on one side of the first region 10 and the second region 20 and between the first region 10 and the second region 20 facing each other. However, in the present specification, since the structure of the well taps 215 and 216 is formed on one side of the first region 10 and the second region 20, the structure of the well taps 215 and 216 does not need to be formed between the first region 10 and the second region 20. The reason is that the structure of the well taps 215 and 216 is omitted between the first region 10 and the second region 20, thereby further securing a space where semiconductor element chips can be formed, by an area of the well taps structure that is omitted in the first conduction type substrate 201.

Accordingly, in the present specification, since the well tap structure does not need to be formed between the first region 10 and the second region 20 facing each other, the number of semiconductor element chips to be formed on the first conduction type substrate 201 can be increased as much, and as a result, the integration of the semiconductor element chips can be increased.

The isolation region 30 may include a deep trench 207. The deep trench 207 may be formed in a boundary region between the first conduction type high-concentration second well region 204 and the second conduction type high-concentration well region 205. Specifically, the deep trench 207 may be formed in the first conduction type high-concentration second well region 204 and the second conduction type high-concentration well region 205 that abut to each other. Here, the deep trench 207 has a second width W2 and has a second depth d2. In this case, the first conduction type may be P type, and the second conduction type may be N type. In this case, while details will be described below, a well tap structure that has been formed in the first conduction type substrate 201 between the first region 10 and the second region 20 in the existing structure is omitted, and the deep trench 207 may be formed instead of multiple shallow trenches and a well tap structure at that position where a well tap structure is omitted. Specifically, in the present embodiment, since an area for forming a well tap structure and shallow trenches is secured, even when the deep trench 207 is formed to have the small second width W2 downward vertically, insulation between the first region 10 and the second region 20 can be effectively achieved.

The deep trench 207 may be formed to the second conduction type doped well region 203 and the first conduction type high-concentration first well region 202 in the first conduction type substrate 201. In the present specification, the deep trench 207 may be formed by a two-step etching process. However, embodiments of the present specification are not limited thereto.

In this case, the second depth d2 of the deep trench 207 may extend to a lower portion of the first conduction type substrate 201 and may be deeper than the first conduction type high-concentration second well region 204 and the second conduction type high-concentration well region 205. The deep trench 207 may be a region that is applied to insulate the first region 10 and the second region 20 from each other.

Accordingly, in the embodiment of the present specification, a well tap structure that is formed to apply a voltage to a well region in the existing structure can be removed in the first conduction type substrate 201 between the first region 10 and the second region 20 facing each other. For this reason, the deep trench 207 having the second width W2 is formed in a portion where a well tap structure is removed, for example, in the first conduction type substrate 201 between the first region 10 and the second region 20, so that the width of the deep trench 207 that is formed to insulate the first region 10 and the second region 20 from each other can be reduced as much. That is, since a well tap structure and a shallow trench structure can be omitted in the first conduction type substrate 201 between the first region 10 and the second region 20 and the deep trench 207 can be formed, an area for forming semiconductor element chips on the first conduction type substrate 201 can be increased.

Accordingly, in another embodiment of the present specification, a well tap structure is omitted in the first conduction type substrate 201 between the first region 10 and the second region 20, thereby increasing an area for forming semiconductor element chips to be provided on the first conduction type substrate 201. In this way, since the number of semiconductor element chips to be formed on the first conduction type substrate 201 can be increased, the integration of the semiconductor element chips can be increased.

The shallow trenches 206 may be filled with a shallow trench insulating film 208. The deep trench 207 may be filled with a deep trench insulating film 209.

In this way, in the present specification, a well tap structure is omitted in the isolation region 30 between the first region 10 and the second region 20 and the deep trench 207 having the small second width W2 compared to the existing structure is provided, thereby further securing an area for semiconductor element chips while achieving high-voltage endurance. As a result, the integration of the semiconductor element chips to be formed on the first conduction type substrate 201 can be increased as much.

Hereinafter, a method of fabricating a semiconductor device according to another embodiment of the present specification will be described with reference to the accompanying drawings.

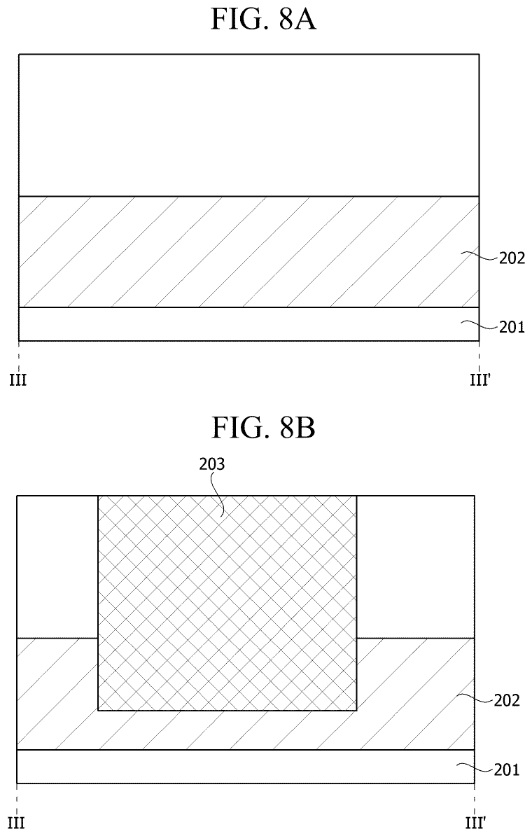

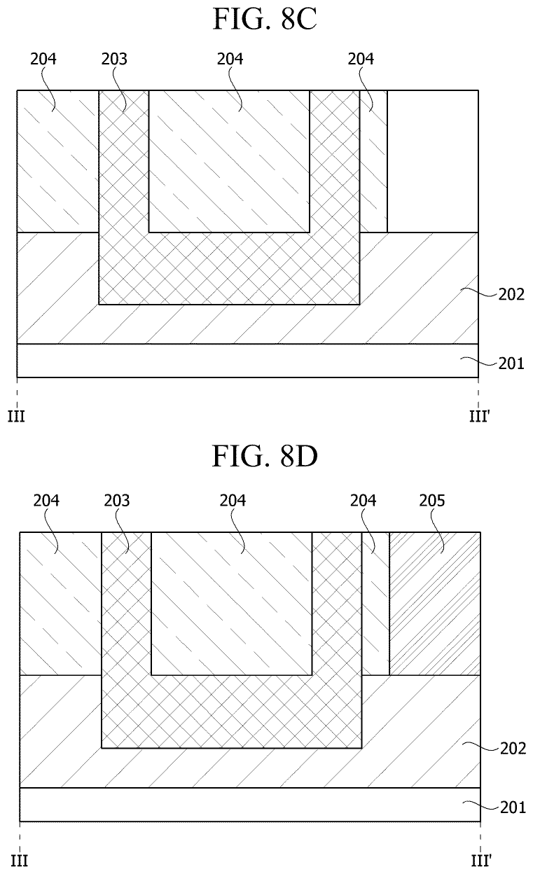

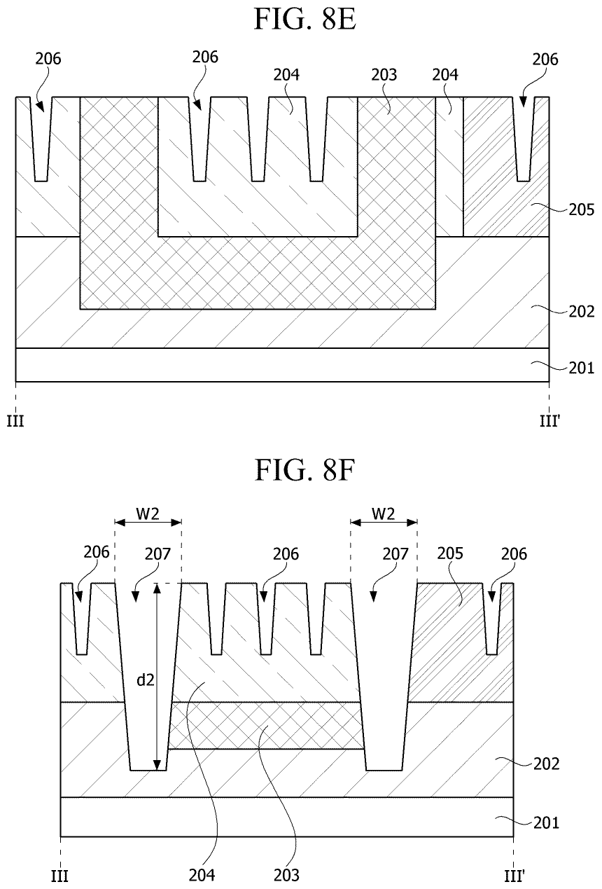

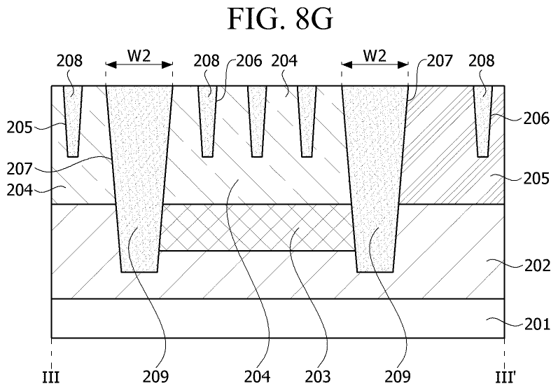

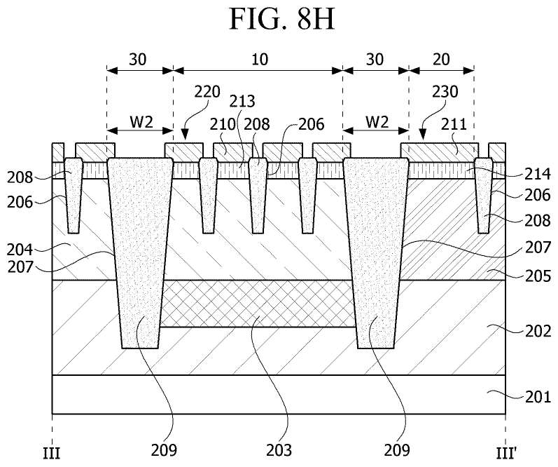

FIGS. 8A to 8H are cross-sectional views of a fabricating process of the semiconductor device according to another embodiment of the present specification.

Referring to FIG. 8A, boron of the first conduction type may be implanted in the first conduction type substrate 201 by blank implantation to form the first conduction type high-concentration first well region 202 in the first conduction type substrate 201. The first conduction type may be p type.

Next, referring to FIG. 8B, phosphorus of the second conduction type may be ion-implanted in the first conduction type substrate 201 using a mask for forming a second conduction type high-concentration well region to form the second conduction type doped well region 203 in the first conduction type high-concentration first well region 202 formed in the first conduction type substrate 201. In this case, the second conduction type may be n type.

Next, referring to FIG. 8C, boron of the first conduction type may be ion-implanted in the first conduction type high-concentration first well region 202 and the second conduction type doped well region 203 using a mask (not illustrated) for forming a first conduction type high-concentration second well region to form the first conduction type high-concentration second well region 204 in the first conduction type high-concentration first well region 202 and the second conduction type doped well region 203. Specifically, the first conduction type high-concentration second well region 204 may be formed on an upper portion of the first conduction type high-concentration first well region 202 and in the second conduction type doped well region 203.

Next, referring to FIG. 8D, phosphorus of the second conduction type may be ion-implanted using a mask for forming a second conduction type high-concentration well region to form the second conduction type high-concentration well region 205 on the first conduction type high-concentration first well region 202. In this case, the second conduction type may be n type.

Next, referring to FIG. 8E, the first conduction type high-concentration second well region 204 and the second conduction type high-concentration well region 205 in the first conduction type substrate 201 may be etched using a shallow trench forming mask (not illustrated) to form the shallow trenches 206 in the first conduction type high-concentration second well region 204 and the second conduction type high-concentration well region 205. However, embodiments of the present specification are not limited thereto.

Next, referring to FIG. 8F, boundary portions between the second conduction type doped well region 203 and the first conduction type high-concentration second well region 204 in the first conduction type substrate 201 may be etched using a deep trench forming mask (not illustrated) to form the deep trenches 207. In this case, the deep trenches 207 may be formed in the first conduction type high-concentration second well region 204 and the second conduction type high-concentration well region 205. The deep trench 207 has the second width W2 and has the second depth d2. While details will be described below, the reason is that a well tap structure that is formed in the existing structure can be removed, thereby securing a marginal area where semiconductor element chips can be formed, on the first conduction type substrate 201 as much.

Accordingly, even when the second width W2 of the deep trench 207 is narrow, an area for insulating the first region 10 and the second region 20 from each other can be secured.

The deep trenches 207 may be formed to the first conduction type high-concentration first well region 202 in the first conduction type substrate 201. The deep trenches 207 may be formed in the first conduction type high-concentration first well region 202, the second conduction type doped well region 203, the first conduction type high-concentration second well region 204, and the second conduction type high-concentration well region 205 in contact with each other. In the present embodiment, the deep trenches 207 may be formed by a two-step etching process. However, embodiments of the present specification are not limited thereto.

In this case, the deep trenches 207 may be formed by etching from an upper surface of the first conduction type substrate 201 at a predetermined depth and may be formed to be narrowed and inclined downward. This is because the deeper an etching depth becomes, the lower the concentration of an etching gas material becomes. The depth of the deep trench 207 may extend to a lower portion of the first conduction type substrate 201 and may be deeper than the first conduction type high-concentration second well region 204 and the second conduction type high-concentration well region 205.

Next, referring to FIG. 8G, the shallow trenches 206 and the deep trenches 207 may be filled with an insulating material, and the shallow trench insulating film 208 and the deep trench insulating film 209 may be formed in the shallow trenches 206 and the deep trenches 207, respectively. In this case, the shallow trench insulating film 208 and the deep trench insulating film 209 may have the same height as the upper surface of the first conduction type substrate 201 or may protrude from the upper surface. The deep trench insulating film 209 may insulate the first region 10 and the second region 20 from each other.

Next, referring to FIG. 8H, a conductive material may be deposited in the first region 10 and the second region 20, and then, may be selectively etched through a mask process to form the first gates 210 and the second gates 211. In this case, the conductive material may be formed of, for example, a polysilicon material. However, embodiments of the present specification are not limited thereto.

Next, a hard mask insulating material (gate hard mask) (not illustrated) may be formed on upper portions of the first and second gates 210 and 211. The hard mask insulating film (not illustrated) can prevent the upper portions of the first and second gates 210 and 211 from being damaged in the etching process.

The sidewall insulating film (see reference number 212 in FIG. 7) may be formed on the side surfaces of the first and second gates 210 and 211.

Next, the second conduction type high-concentration doped regions 213 and the first conduction type high-concentration doped regions 214 may be formed in the first conduction type substrate 201 below the side surfaces of the first and second gates 210 and 211 that compose the first and second semiconductor elements 220 and 230 in the first region 10 and the second region 20, respectively. In this case, the second conduction type high-concentration doped regions 213 may be formed in the first conduction type high-concentration second well region 204 of the first region 10. The second conduction type high-concentration doped regions 213 may be formed in the first conduction type high-concentration second well region 204 below both sides of the first gate 210. The first semiconductor element 220 may include the first gate 210 and the second conduction type high-concentration doped regions 213.

The first conduction type high-concentration doped regions 214 may be formed in the second conduction type high-concentration well region 205 of the second region 20. In this case, the first conduction type high-concentration doped regions 214 may be formed in the second conduction type high-concentration well region 205 below both sides of the second gate 211. The second semiconductor element 230 may include the second gate 211 and the second conduction type high-concentration doped regions 214.

Referring to FIG. 7, the first and second well taps 215 and 216 may be formed in the first conduction type substrate 201 between the shallow trenches 206 on one side of the first region 10. In this case, the first and second well taps 215 and 216 may serve to apply a voltage to a well region. In this case, the first well tap 215 may be formed in the first conduction type high-concentration second well region 204. The second well tap 216 may be formed in the second conduction type doped well region 203.

Referring to FIG. 5, the first and second well taps 215 and 216 may be formed on one side of the first region 10 and the second region 20. Meanwhile, referring to FIG. 5, the first and second well taps 215 and 216 are not present in the first conduction type substrate 201 between the first region 10 and the second region 20 facing each other.

Specifically, referring to FIG. 7, the first and second well taps 215 and 216 may be formed in the first conduction type high-concentration second well region 204 and the second conduction type doped well region 203 formed in the first conduction type substrate 201. Meanwhile, the first and second well taps 215 and 216 are not present in the first conduction type substrate 201 between the first region 10 and the second region 20.

In the existing structure, the structures of the first and second well taps 215 and 216 for applying a voltage to a well region are formed on one side of the first region 10 and the second region 20 and between these regions; however, in the present specification, since the structures of the first and second well taps 215 and 216 are formed on one side of the first region 10 and the second region 20, the structures of the first and second well taps 215 and 216 do not need to be formed between the first region 10 and the second region 20. The reason is that the structures of the first and second well taps 215 and 216 are omitted between the first region 10 and the second region 20, thereby further securing a space where semiconductor element chips can be formed, by an area of a well tap structure that is omitted in the first conduction type substrate 201.

Accordingly, in the present specification, since a well tap structure does not need to be formed between the first region 10 and the second region 20, the number of semiconductor element chips to be formed on the first conduction type substrate 201 can be increased as much, and as a result, the integration of the semiconductor element chips can be increased.

On the other hand, a method of fabricating a semiconductor device according to still another embodiment of the present specification will be described with reference to the accompanying drawings described below.

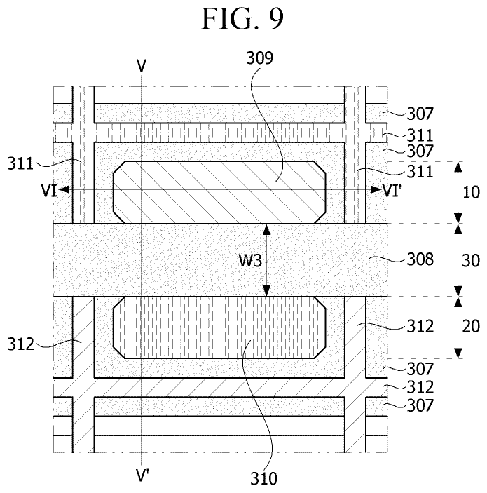

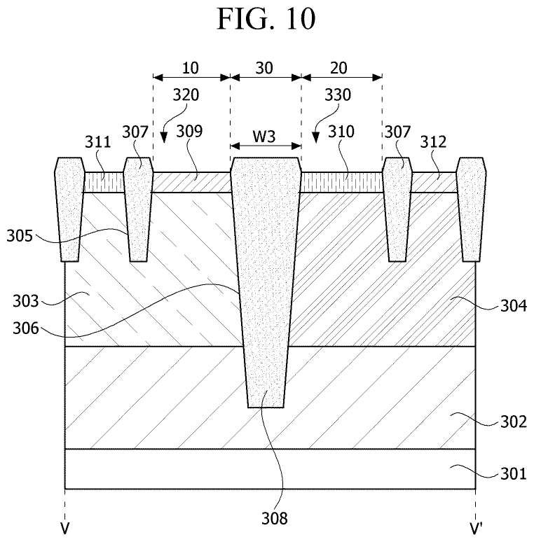

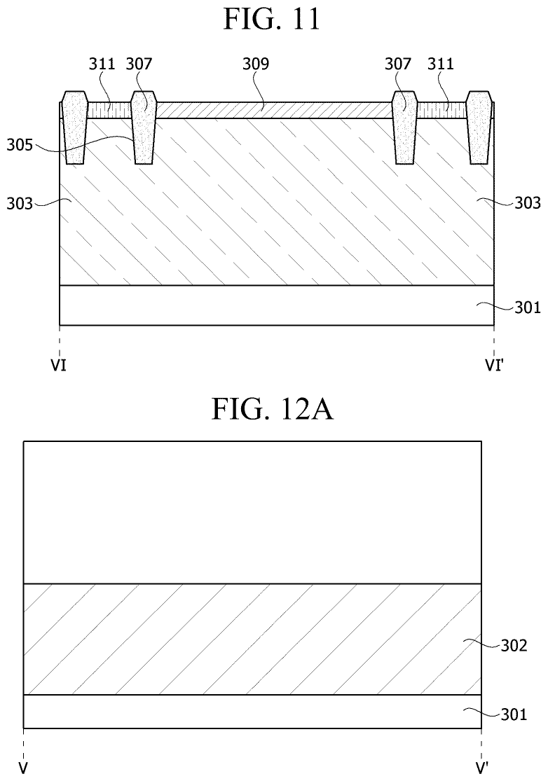

FIG. 9 is a plan view of a semiconductor device according to still another embodiment of the present specification. FIG. 10 is a cross-sectional view taken along line V-V′ in FIG. 9. FIG. 11 is a cross-sectional view taken along line VI-VI′ in FIG. FIG. 9.

Referring to FIGS. 9 to 11, the semiconductor device according to still another embodiment of the present specification may include a first region 10 having a plurality of second conduction type diodes 309 in a first conduction type substrate 301, a second region 20 having a plurality of first conduction type diodes 310 in the first conduction type substrate 101, and an isolation region 30 positioned between the first region 10 and the second region 20 to separate the first region 10 and the second region 20 from each other.

Here, a first conduction type high-concentration first well region 302 may be formed in the first conduction type substrate 301. A first conduction type high-concentration second well region 303 and a second conduction type high-concentration well region 304 may be formed on the first conduction type high-concentration first well region 302 in the first conduction type substrate 301. The first conduction type may be P type, and the second conduction type may be N type.

Referring to FIGS. 10 and 11, the first region 10 may include the first conduction type high-concentration second well region 303 and the second conduction type diode 309 in the first conduction type substrate 301.

The second region 20 may include the second conduction type high-concentration well region 304 and the first conduction type diode 310 in the first conduction type substrate 301.

Referring to FIG. 10, shallow trenches 305 may be formed in the first conduction type substrate 301 between the second conduction type diode 309 and a first well tap 311 in the first region 10 and between the first conduction type diode 310 and a second well tap 312 in the second region 20.

The shallow trenches 305 may be filled with a shallow trench insulating film 307. In this case, the shallow trench insulating film 307 may be formed to have the same height as the first conduction type substrate 301 or may be formed to protrude at a height higher than the first conduction type substrate 301.

A deep trench 306 may be formed in the first conduction type substrate 301 positioned in the isolation region 30 between the first region 10 and the second region 20. The deep trench 306 may be filled with a deep trench insulating film 308. The deep trench insulating film 308 may be formed to have the same height as the first conduction type substrate 301 or may be formed to protrude at a height higher than the first conduction type substrate 301.

The first well tap 311 may be formed in the first conduction type substrate 301 between the shallow trenches 305 on one side of the first region 10, and the second well tap 312 may be formed in the first conduction type substrate 301 between the shallow trenches 305 on one side of the second region 20. In this case, the first and second well taps 311 and 312 may serve to apply a voltage to a well region. Specifically, the first well tap 311 may be formed in the first conduction type high-concentration second well region 303 formed in the first conduction type substrate 301. The first well tap 311 may be formed in the first conduction type high-concentration second well region 303 formed in the first conduction type substrate 301 on the outer periphery of the second conduction type diode 309 in the first region 10.

The second well tap 312 may be formed in the second conduction type high-concentration well region 304 formed in the first conduction type substrate 301. The second well tap 312 may be formed in the second conduction type high-concentration well region 304 formed in the first conduction type substrate 301 on the outer periphery of the first conduction type diode 310 in the second region 20.

The first and second well taps 311 and 312 may not be present in the isolation region 30, for example, in the first conduction type substrate 301 between the first region 10 and the second region 20 facing each other. The reason is that, when the first and second well taps 311 and 312 are present between the first region 10 and the second region 20, the first and second well taps 311 and 312 may unnecessarily occupy the area of the first conduction type substrate 301, and an area for forming semiconductor element chips may be reduced.

Specifically, in the existing structure, multiple shallow trenches are present in the isolation region 30 between the first region 10 and the second region 20 along with the structures of the first and second well taps.

Meanwhile, in the present embodiment, the first and second well taps 311 and 312 are not formed between the first region 10 and the second region 20, thereby further securing an area for forming semiconductor element chips in the first conduction type substrate 301.

One deep trench 306 having a third width W3 is formed in the isolation region 30 between the first region 10 and the second region 20 instead of multiple shallow trenches, thereby effectively insulating the first region 10 and the second region 20 from each other.

In this way, in the existing structure, the structures of the first and second well taps 311 and 312 are formed in the isolation region 30 that is a region between the first region 10 and the second region 20; however, in the present specification, the structures of the first and second well taps 311 and 312 may not be formed between the first region 10 and the second region 20. The reason is that the structures of the first and second well taps 311 and 312 are omitted between the first region 10 and the second region 20, thereby further securing an area where semiconductor element chips can be formed in the first conduction type substrate 301, by an area of a well tap structure. Since the structures of the first and second well taps 311 and 312 are formed outside the first region 10 and the second region 20, even when the structures of the first and second well taps 311 and 312 are not formed between the first region 10 and the second region 20, a voltage can be applied to a well region.

Accordingly, in the present specification, since a well tap structure is not formed between the first region 10 and the second region 20, the number of semiconductor element chips to be formed in the first conduction type substrate 301 can be increased as much, and as a result, the integration of the semiconductor element chips may be increased.

On the other hand, a method of fabricating a semiconductor device according to still another embodiment of the present specification will be described with reference to the accompanying drawings.

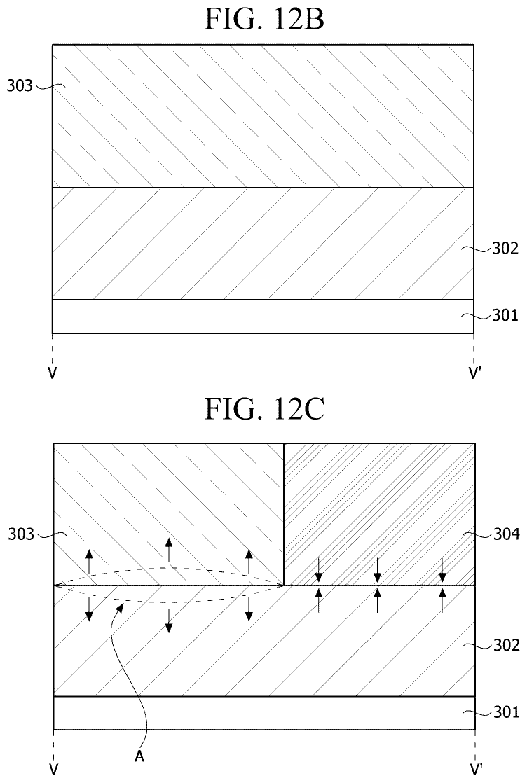

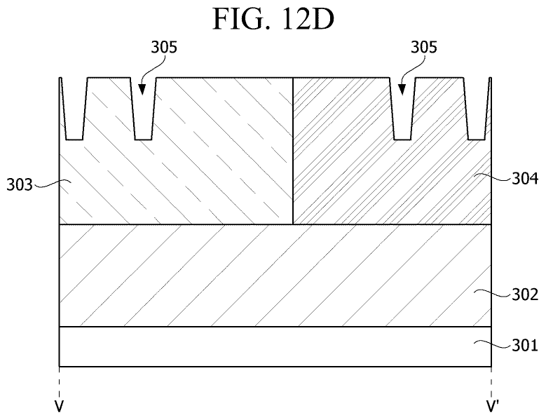

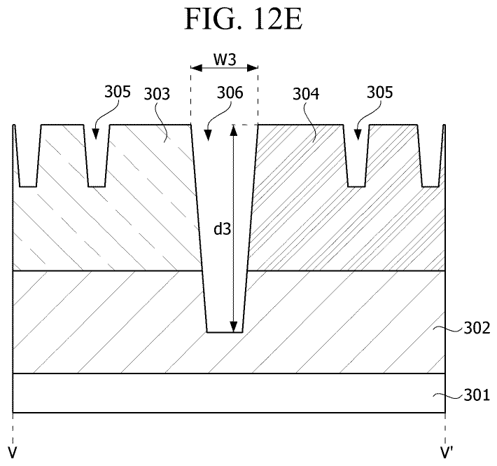

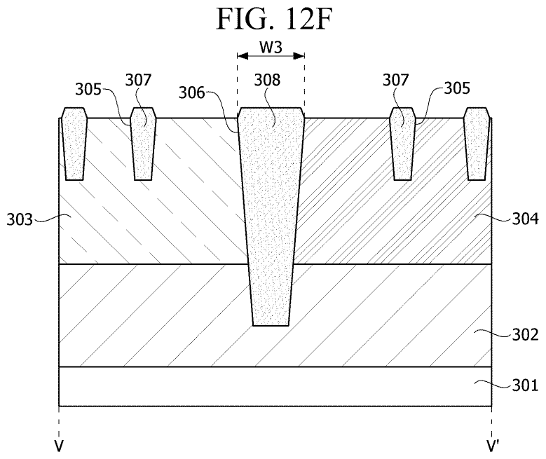

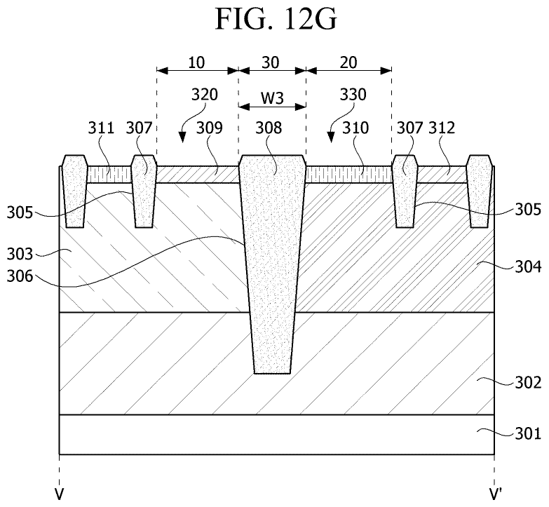

FIGS. 12A to 12G are cross-sectional views of a fabricating process of the semiconductor device according to still another embodiment of the present specification.

Referring to FIG. 12A, boron of the first conduction type may be implanted in the first conduction type substrate 301 by blank implantation to form the first conduction type high-concentration first well region 302 in the first conduction type substrate 301. The first conduction type may be p type.

Next, referring to FIG. 12B, phosphorus of the second conduction type may be ion-implanted in the first conduction type substrate 301 to form the second conduction type high-concentration well region 304 on the first conduction type high-concentration first well region 302 in the first conduction type substrate 301. In this case, the second conduction type may be N type.

Next, referring to FIG. 12C, boron of the first conduction type may be ion-implanted in the first conduction type substrate 301 using a mask (not illustrated) to form the first conduction type high-concentration second well region 303 on the first conduction type high-concentration first well region 302. In this case, the first conduction type high-concentration second well region 303 and the second conduction type high-concentration well region 304 are in contact with each other. In this case, the first conduction type may be P type.

As indicated by A in FIG. 12C, in a boundary region between the first conduction type high-concentration second well region 303 and the first conduction type high-concentration first well region 302, first conduction type ions having the same polarity may repel each other and may be moved to the first conduction type high-concentration first well region 302 and the first conduction type high-concentration second well region 303.

Meanwhile, in a boundary region between the first conduction type high-concentration first well region 302 and the second conduction type high-concentration well region 304, first conduction type ions and second conduction type ions having different polarities may be diffused.

Next, referring to FIG. 12D, the first conduction type high-concentration second well region 303 and the second conduction type high-concentration well region 304 in the first conduction type substrate 301 may be etched using a shallow trench forming mask (not illustrated) to form the shallow trenches 305 in the first conduction type high-concentration second well region 303 and the second conduction type high-concentration well region 304.

Next, referring to FIG. 12E, a boundary portion between the first conduction type high-concentration second well region 303 and the second conduction type high-concentration well region 304 in contact with each other in the first conduction type substrate 301 may be etched using a deep trench forming mask (not illustrated) to form the deep trench 306. In this case, the deep trench 306 may be formed in the first conduction type high-concentration second well region 303 and the second conduction type high-concentration well region 304. Here, the deep trench 306 has the third width W3 and has a third depth d3. In this case, the third width W3 may be a small width compared to the existing structure. While details will be described below, the reason is that a well tap structure that is formed in the isolation region 30 in the existing structure can be omitted, thereby securing a marginal area where semiconductor element chips can be formed, in the first conduction type substrate 301 as much. As a result, even when the third width W3 of the deep trench 306 is narrow compared to the existing structure, the first region 10 and the second region 20 can be insulated from each other.

The deep trench 306 may be formed to the first conduction type high-concentration first well region 302 in the first conduction type substrate 301. The deep trench 306 may be formed in the first conduction type high-concentration second well region 303 and the second conduction type high-concentration well region 304 in contact with each other. In the present embodiment, the deep trench 306 may be formed by a two-step etching process. However, embodiments of the present specification are not limited thereto.

Specifically, the depth of the deep trench 306 may extend to a lower portion of the first conduction type substrate 301 and may be deeper than the first conduction type high-concentration second well region 303 and the second conduction type high-concentration well region 304.

Next, referring to FIG. 12F, the shallow trenches 305 and the deep trench 306 may be filled with an insulating material, and the shallow trench insulating film 307 and the deep trench insulating film 308 may be formed in the shallow trenches 305 and the deep trench 306, respectively. In this case, the shallow trench insulating film 307 and the deep trench insulating film 308 may have the same height as an upper surface of the first conduction type substrate 301 or may protrude from the upper surface. The deep trench insulating film 308 may insulate the first region 10 and the second region 20 from each other.

Next, referring to FIG. 12G, the second conduction type diode 309 and the first conduction type diode 310 may be formed in the first conduction type substrate 301 positioned in the first region 10 and the second region 20. In this case, the second conduction type diode 309 may be formed in the first conduction type high-concentration second well region 303 of the first region 10. The first conduction type diode 310 may be formed in the second conduction type high-concentration well region 304.

The first and second well taps 311 and 312 may be formed in the first conduction type substrate 301 between the shallow trenches 305 on one side of the first region 10 and the second region 20. In this case, the first and second well taps 311 and 312 may serve to apply a voltage to a well region.

Specifically, the first well tap 311 may be formed in the first conduction type high-concentration second well region 303 formed in the first conduction type substrate 301. The first well tap 311 may be formed in the first conduction type high-concentration second well region 303 formed in the first conduction type substrate 301 on the outer periphery of the second conduction type diode 309 in the first region 10.

The second well tap 312 may be formed in the second conduction type high-concentration well region 304 formed in the first conduction type substrate 301. The second well tap 312 may be formed in the second conduction type high-concentration well region 304 formed in the first conduction type substrate 301 on the outer periphery of the first conduction type diode 310 in the second region 20.

The first and second well taps 311 and 312 may not be present in the isolation region 30, for example, in the first conduction type substrate 301 between the first region 10 and the second region 20 facing each other. The reason is that, when the first and second well taps 311 and 312 are present between the first region 10 and the second region 20, the first and second well taps 311 and 312 may unnecessarily occupy the area of the first conduction type substrate 301, and an area for forming semiconductor element chips may be reduced.

Specifically, in the existing structure, multiple shallow trenches are present in the isolation region 30 between the first region 10 and the second region 20 along with the structures of the first and second well taps.

Meanwhile, in the present embodiment, the first and second well taps 311 and 312 are not formed between the first region 10 and the second region 20, thereby further securing an area for forming semiconductor element chips in the first conduction type substrate 301.

One deep trench 306 having a third width W3 is formed in the isolation region 30 between the first region 10 and the second region 20 instead of multiple shallow trenches, thereby effectively insulating the first region 10 and the second region 20 from each other.

Accordingly, the embodiments disclosed herein are provided for illustrative purposes and are not intended to limit the technical concept of the present specification, and the scope of the technical concept of the present specification is not limited to these embodiments.

Therefore, it should be understood that the embodiments described above are illustrative in all aspects and are not intended to be limiting.

The scope of protection of the present invention should be construed on the basis of the following claims, and all technical concepts within the equivalent scope thereof should be construed as falling within the scope of the present invention.

### LIST OF REFERENCE NUMBERS

10: First region
20: Second region
30: First isolation region
40: Second isolation region
101: First conduction type substrate
102: First conduction type high-concentration first well region
103: Second conduction type high-concentration well region
104: First conduction type high-concentration second well region
105: Shallow trench
106: Deep trench
107: Shallow trench insulating film
108: Deep trench insulating film
110: First gate
111: Second gate
120: First semiconductor element
130: Second semiconductor element
W1: First width

What is claimed is:

1. A semiconductor device comprising:
a first region where a plurality of first semiconductor elements are provided on a substrate;
a second region where a plurality of second semiconductor elements are provided on the substrate;
an isolation region provided in the substrate between the first region and the second region;
shallow trenches formed in the substrate of the first region and the second region;
a shallow trench insulating film formed inside each of the shallow trenches;
a deep trench formed in the substrate in the isolation region; and
a deep trench insulating film formed inside the deep trench,
wherein a well tap structure is not provided in the substrate between the first region and the second region.

2. The semiconductor device according to claim 1, further comprising:
a first conduction type high-concentration first well region formed in the substrate; and
a second conduction type high-concentration well region and a first conduction type high-concentration second well region formed on the first conduction type high-concentration first well region.

3. The semiconductor device according to claim 2, wherein the deep trench is formed across the second conduction type high-concentration well region, the first conduction type high-concentration second well region, and the first conduction type high-concentration first well region.

4. The semiconductor device according to claim 1, further comprising:
a first conduction type high-concentration first well region formed in the substrate;
a second conduction type doped well region formed on the first conduction type high-concentration first well region;
a first conduction type high-concentration second well region formed on an upper portion of the first conduction type high-concentration first well region and in the second conduction type doped well region; and
a second conduction type high-concentration well region formed on an upper portion of the first conduction type high-concentration first well region.

5. The semiconductor device according to claim 4, wherein the deep trench is formed across the second conduction type high-concentration well region, the first conduction type high-concentration second well region, the second conduction type doped well region, and the first conduction type high-concentration first well region.

6. The semiconductor device according to claim 2, wherein the shallow trenches are formed in the first conduction type high-concentration second well region and the second conduction type high-concentration well region.

7. The semiconductor device according to claim 1, wherein a well tap structure is provided in the substrate on one side of the first region and the second region.

8. The semiconductor device according to claim 7, wherein the well tap structure is formed in the substrate between the shallow trenches on one side of the first region and the second region.

9. The semiconductor device according to claim 1, wherein each of the first semiconductor elements includes a first gate formed on the substrate of the first region and first conduction type high-concentration doped regions formed in the substrate below both sides of the first gate, and each of the second semiconductor elements includes a second gate formed on the substrate of the second region and second conduction type high-concentration doped regions formed in the substrate below both sides of the second gate.

10. The semiconductor device according to claim 1, wherein each of the first semiconductor elements includes a second conduction type diode formed in the substrate of the first region, and each of the second semiconductor elements includes a first conduction type diode formed in the substrate of the second region.

11. A method of fabricating a semiconductor device, the method comprising:
preparing a first region having a plurality of first semiconductor elements on a substrate and a second region having a plurality of second semiconductor elements on the substrate;
preparing an isolation region in the substrate between the first region and the second region;
forming shallow trenches in the substrate of the first region and the second region;
forming a deep trench in the substrate in the isolation region; and
forming a shallow trench insulating film inside each of the shallow trench and forming a deep trench insulating film inside the deep trench.

12. The method of fabricating a semiconductor device according to claim 11, further comprising:
forming a first conduction type high-concentration first well region in the substrate; and
forming a second conduction type high-concentration well region and a first conduction type high-concentration second well region on the first conduction type high-concentration first well region.

13. The method of fabricating a semiconductor device according to claim 12, wherein the forming of the deep trench includes forming the deep trench across the second conduction type high-concentration well region, the first conduction type high-concentration second well region, and the first conduction type high-concentration first well region.

14. The method of fabricating a semiconductor device according to claim 11, further comprising:
forming a first conduction type high-concentration first well region in the substrate;
forming a second conduction type doped well region on the first conduction type high-concentration first well region;
forming a first conduction type high-concentration second well region on an upper portion of the first conduction type high-concentration first well region and in the second conduction type doped well region; and
forming a second conduction type high-concentration well region on an upper portion of the first conduction type high-concentration first well region.

15. The method of fabricating a semiconductor device according to claim 14, wherein the forming of the deep trench includes forming the deep trench across the second conduction type high-concentration well region, the first conduction type high-concentration second well region, the second conduction type doped well region, and the first conduction type high-concentration first well region.

16. The method of fabricating a semiconductor device according to claim 12, wherein the forming of the shallow trenches includes forming the shallow trenches in the first conduction type high-concentration second well region and the second conduction type high-concentration well region.

17. The method of fabricating a semiconductor device according to claim 11, further comprising:
forming a well tap structure in the substrate on one side of the first region and one side of the second region.

18. The method of fabricating a semiconductor device according to claim 17, wherein the forming of the well tap structure includes forming the well tap structure in the substrate between the shallow trenches on one side of the first region and the second region and not forming a well tap structure in the substrate that abuts to the deep trench.

19. The method of fabricating a semiconductor device according to claim 12,
wherein the preparing of the first region having the first semiconductor elements includes forming a first gate on the substrate of the first region, and forming first conduction type high-concentration doped regions in a second conduction type high-concentration well region in the substrate below both sides of the first gate, and
the preparing of the second region having the second semiconductor elements includes forming a second gate on the substrate of the second region, and forming second conduction type high-concentration doped regions in the first conduction type high-concentration second well region in the substrate below both sides of the second gate.

20. The method of fabricating a semiconductor device according to claim 12,
wherein the preparing of the first region having the first semiconductor elements includes forming a second conduction type diode in a first conduction type high-concentration second well region in the substrate of the first region, and
the preparing of the second region having the second semiconductor elements includes forming a first conduction type diode in a second conduction type high-concentration well region in the substrate of the second region.
